(19) United States
(12) Patent Application Publication
(10) Pub. No.: US 2017/0005160 A1
(43) Pub. Date: Jan. 5, 2017

(54) ANCHORING CONDUCTIVE MATERIAL IN SEMICONDUCTOR DEVICES

(71) Applicant: QUALCOMM Incorporated, San Diego, CA (US)

(72) Inventors: Shiqun GU, San Diego, CA (US); Yue LI, San Diego, CA (US); Ratibor RADOJCIC, San Diego, CA (US)

(21) Appl. No.: 14/973,479

(22) Filed: Dec. 17, 2015

Related U.S. Application Data
(60) Provisional application No. 62/187,614, filed on Jul. 1, 2015.

(51) Int. Cl. H01L 49/02; H01L 23/532; H01L 23/522

(52) U.S. Cl. CPC H01L 28/60; H01L 23/5223; H01L 23/53228

(57) ABSTRACT

Copper (Cu) grain boundaries can move during a thermal cycle resulting in the Cu grain position being offset. Such Cu pumping can disturb the surface of a bottom metal, and can physically break a dielectric of a metal-insulator-metal (MIM) capacitor. By capping the bottom metal with an anchoring cap, Cu pumping is reduced or eliminated.

### CROSS-REFERENCE TO RELATED APPLICATIONS

The present Application for Patent claims the benefit of U.S. Provisional Application No. 62/187,614, entitled “ANCHORING CONDUCTIVE MATERIAL IN SEMICONDUCTOR DEVICES,” filed Jul. 1, 2015, assigned to the assignee hereof, and expressly incorporated herein by reference in its entirety.

### FIELD OF DISCLOSURE

One or more aspects of this disclosure relate generally to anchoring conductive material in semiconductor devices. In particular, one or more of aspects of this disclosure relate to anchoring conductive material in semiconductor devices to enable high density and low equivalent series resistance (ESR) metal-insulator-metal (MIM) capacitors.

### BACKGROUND

Capacitors are elements that are used extensively in integrated circuits. In their simplest form, capacitors essentially comprise two conductive plates separated by a dielectric material, which is basically an insulator. The capacitance, or amount of charge held by the capacitor per applied voltage, depends on a number of parameters such as the area of the plates, the distance between the plates, and the dielectric constant value of the insulator between the plates. Capacitors can be used in filters, analog-to-digital converters, memory devices, control applications, analog and RF applications, and many other types of semiconductor devices.

One type of capacitor is a metal-insulator-metal (MIM) capacitor, which is typically formed with two metal plates sandwiching a dielectric layer. MIM capacitors are frequently used in integrated circuits such as mixed signal devices and logic semiconductor devices. In devices, a MIM capacitor is typically inserted between two thick metal layers. FIG. 1 illustrates an example. In FIG. 1, a device 100 includes a MIM capacitor 110 and a multi-layer connector 150 in an insulator layer 180. The MIM capacitor 110 includes an upper plate 112, a lower plate 114 and a dielectric layer 116 in between the upper and lower plates 112, 114. A first top metal 130 is connected to the upper plate 112 through a first capacitor interconnect 135, and a second top metal 140 is connected to the lower plate 114 through a second capacitor interconnect 145. The multi-layer connector 150 includes an upper terminal 160 connected to a lower terminal 170 through a terminal interconnect 165. The upper and lower terminals 160, 170 can be used to interconnect multiple layers of semiconductor devices including multiple dies. Note that the MIM capacitor 110 is positioned vertically in between the upper and lower terminals 160, 170.

Semiconductor devices are becoming increasingly dense. The number of transistors on a given area of a wafer continues to grow exponentially. For power distribution network (PDN) applications, higher capacitor density is desired. High capacitance MIM capacitors have been used to achieve highly dense devices. To achieve capacitor density on the order of 5-50 nF/mm², MIM capacitors with thin high-K (dielectric constant) dielectric down to 10 nm are required. Since high capacitance is desired, the dielectric layer of the MIM capacitor should be as thin as practicable.

Unfortunately, the thinness of the dielectric layer can be problematic. When a thick terminal is formed of copper (Cu), the Cu grain boundaries can move during a thermal cycle resulting in the Cu grain position being offset. This thermal cycle induced movement is referred to as “pumping”. A device can undergo thermal cycles as it is turned on/off many times during its operation. In FIG. 2, 200-A represents an example of a thick terminal formed of copper (Cu) after initial fabrication, and 200-B represents the same terminal after being subjected to thermal cycling. Note that the top of the terminal 200-A is relatively flat. However, during thermal cycles, the Cu grains regroup which can result in the surface of the terminal 200-A being disturbed. As seen, the pumping can result in a part of the terminal 200-B jutting out from the top surface such that the top surface of the terminal 200-B is no longer flat.

Referring back to FIG. 1, note that there is no terminal located below the MIM capacitor 110. If a MIM capacitor is placed on or above a thick Cu terminal, the Cu pumping can disturb the surface of the terminal. Due to the thinness of the dielectric layer 116, the Cu pumping can physically break the dielectric layer 116. This in turn can lead to leakage and cause the capacitor to malfunction. Thus, conventional device design rules prohibit MIM capacitors from landing on top of a terminal. That is, conventional design rules prohibit routing of signal paths below the MIM capacitors.

### SUMMARY

This summary identifies features of some example aspects, and is not an exclusive or exhaustive description of the disclosed subject matter. Whether features or aspects are included in, or omitted from this summary is not intended as indicative of relative importance of such features. Additional features and aspects are described, and will become apparent to persons skilled in the art upon reading the following detailed description and viewing the drawings that form a part thereof

One or more aspects are directed to a semiconductor device. The semiconductor device may comprise a bottom metal with an anchoring cap formed thereon, a MIM capacitor formed above the bottom metal, a first top metal electrically coupled to an upper plate of the MIM capacitor through a first capacitor interconnect, and a second top metal electrically coupled to a lower plate of the MIM capacitor through a second capacitor interconnect. At least a portion of the bottom metal may overlap at least a portion of the lower plate of the MIM capacitor. In one embodiment, the bottom metal may be electrically coupled to the lower plate of the MIM capacitor. In another embodiment, a separation layer may electrically separate the bottom metal and the MIM capacitor.

One or more aspects are directed to a method of manufacturing a semiconductor device. The method may comprise forming a bottom metal with an anchoring cap thereon, forming a MIM capacitor above the bottom metal, forming a first top metal electrically coupled to an upper plate of the MIM capacitor through a first capacitor interconnect, and forming a second top metal electrically coupled to a lower plate of the MIM capacitor through a second capacitor interconnect. The semiconductor device may be formed such that at least a portion of the bottom metal overlaps at least a portion of the lower plate of the MIM capacitor. In one embodiment, the semiconductor device may be formed such that the bottom metal is electrically coupled to the lower plate of the MIM capacitor. In another embodiment, the semiconductor device may be formed such that a separation layer electrically separates the bottom metal and the MIM capacitor.

One or more aspects are directed to a semiconductor device. The semiconductor device may comprise a MIM capacitor and a top metal formed on the MIM capacitor. The MIM capacitor may comprise a bottom metal with an anchoring cap formed thereon, a dielectric layer formed on the bottom metal, and a capacitor interconnect formed on the dielectric layer. The top metal may be formed on and electrically coupled to the capacitor interconnect.

One or more aspects are directed to a method of manufacturing a semiconductor device. The method may comprise forming a MIM capacitor, and forming a top metal on the MIM capacitor. The MIM capacitor may be formed by forming a bottom metal and an anchoring cap on the bottom metal, forming a dielectric layer on the bottom metal, and forming a capacitor interconnect on the dielectric layer. The semiconductor device may be formed such that the top metal is formed on and electrically coupled to the capacitor interconnect.

### BRIEF DESCRIPTION OF THE DRAWINGS

The accompanying drawings are presented to aid in the description of embodiments and are provided solely for illustration of the embodiments and not limitation thereof

FIG. 1 illustrates a MIM capacitor placement in a semiconductor device;

FIG. 2 illustrates a grain boundary movement induced pumping due to thermal cycle;

FIG. 3 illustrates anchoring of a conductive material to minimize or eliminate pumping;

FIGS. 4A and 4B illustrate embodiments of semiconductor devices;

FIGS. 5A-5F illustrate various fabrication stages of an example process to manufacture a semiconductor device;

FIG. 6 illustrates a flow chart of an example method to manufacture a semiconductor device;

FIG. 7 illustrates an embodiment of a semiconductor device;

FIGS. 8A-8E illustrate various fabrication stages of another example process to manufacture a semiconductor device;

FIG. 9 illustrates a flow chart of another example method to manufacture a semiconductor device; and

FIG. 10 illustrates examples of apparatuses with a semiconductor device integrated therein.

### DETAILED DESCRIPTION

Examples are disclosed in the following description and related drawings directed to specific embodiments of one or more aspects of the present disclosure. Alternate embodiments may be devised without departing from the scope of the discussion. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments of the disclosed subject matter include the discussed feature, advantage or mode of operation.

The terminology used herein is for the purpose of describing particular embodiments only and is not intended to be limiting. As used herein, the singular forms “a”, “an”, and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence of actions described herein can be considered to be embodied entirely within any form of computer-readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

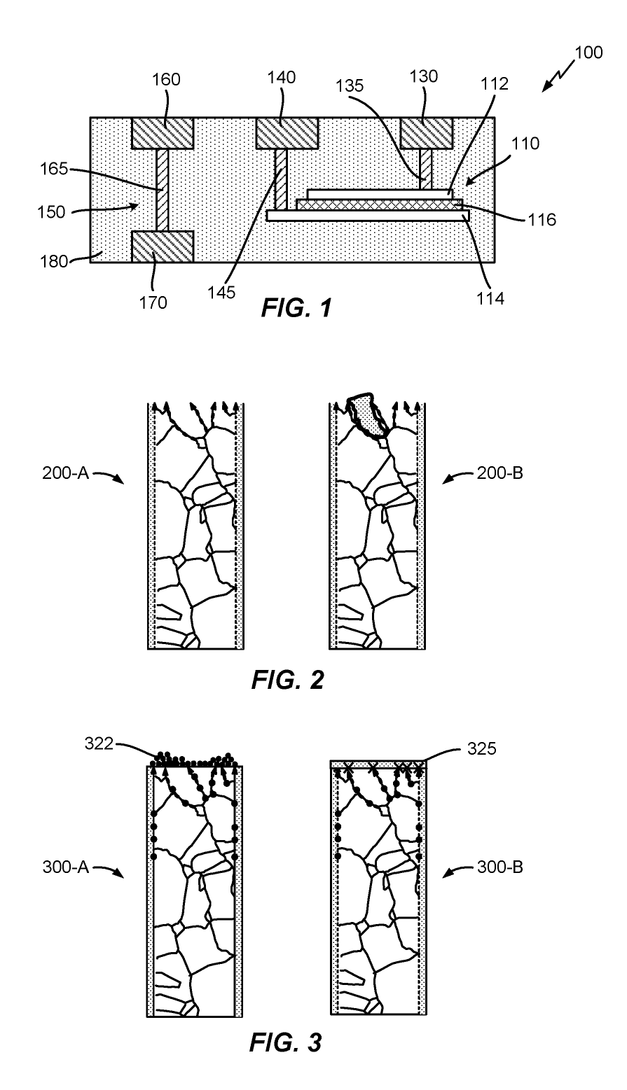

It is mentioned above that conventional design rules prohibit MIM capacitors from landing on a terminal. First, the area below the MIM capacitor cannot be used for routing. As semiconductor processes scale down, the real estate available for routing signals decreases. Thus, prohibiting signal routing below the MIM capacitor further aggravates the lack of available real estate. Second, the thicknesses of the upper and/or the lower plates of the MIM capacitor are also reduced to increase densities. See FIG. 1. This has the undesirable effect of increasing the equivalent series resistance (ESR).

Various aspects of the disclosed subject matter address one or more shortcomings of the conventional semiconductor device and/or method. In one or more embodiments, terminals and/or electrodes may be capped with anchoring materials. This is explained with reference to FIG. 3. In this figure, 300-A represents an example of a terminal at a stage of fabrication according to an aspect of the present disclosure. The terminal may be formed from copper (Cu). At this stage, an anchoring material 322 (illustrated as granules) may be provided. Examples of anchoring materials include Co, Mn, CoWP, CoSnP, and Pd. The anchoring material 322, which may be used to form an anchoring cap 325, can minimize grain boundary movements of the terminal 300-A. 300-B represents the same terminal at another fabrication stage. The terminal 300-B may result from one or more processes that involve high temperatures including a chemical vapor deposition, a physical vapor deposition, or other thermal annealing process(es). The anchoring cap 325 (or simply “cap”) is formed on a surface of the terminal. The cap 325 can significantly reduce or even eliminate Cu pumping due to thermal cycles. That is, the terminal 300-B is much more likely to maintain its shape. The cap 325 is electrically conductive.

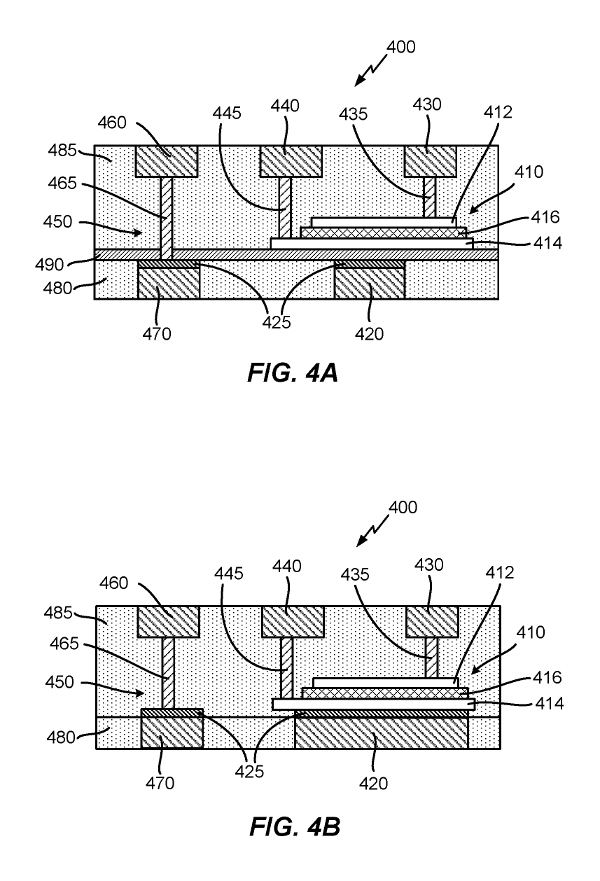

FIGS. 4A and 4B illustrate embodiments of semiconductor devices according to one or more aspects of the present disclosure. The semiconductor devices 400 of these figures have the following in common. Each semiconductor device 400 is shown as including three upper conductors (a first top conductor 430, a second top conductor 440 and an upper terminal 460) and two lower conductors (a bottom conductor 420 and a lower terminal 470). This is merely for illustrative purposes, and the semiconductor device 400 can include any number of upper and lower conductors. Any one or more of the upper and lower conductors may be formed from any appropriate electrically conductive materials including metals such as copper (Cu).

Note that phrases such as “top”, “bottom”, “upper”, “lower”, etc. should not be taken in a limiting sense. For example, there is no requirement that an upper conductor be physically above a lower conductor unless explicitly indicated, nor is there a requirement that the top conductor be physically the highest located conductor.

Also, it will be assumed that the upper and lower conductors are formed from metals such as copper (Cu). The first top conductor 430, the second top conductor 440 and the bottom conductor 420 may respectively be referred to as the first top metal 430, the second top metal 440, and the bottom metal 420. This is simply for ease of description, and not a limitation.

In both FIGS. 4A and 4B, a terminal interconnect 465 may electrically couple the upper and lower terminals 460, 470. An example of the terminal interconnect 465 is a conductive through-silicon via (TSV). The upper and lower terminals 460, 470 and the terminal interconnect 465 may form a multi-layer connector 450, e.g., to enable electrical connections between devices above and below the multi-layer connector 450 (not shown). Also while not shown, electrical connections to and from devices in a same layer can be made.

Each semiconductor device 400 may include a MIM capacitor 410, which may comprise an upper plate 412, a dielectric layer 416, and a lower plate 414. The upper plate 412 of the MIM capacitor 410 may be electrically coupled with the first top metal 430 through a first capacitor interconnect 435. Similarly, the lower plate 414 of the MIM capacitor 410 may be electrically coupled with the second top metal 440 through a second capacitor interconnect 445. In this way, the first and second top metals 430, 440 may serve as electrodes of the MIM capacitor 410. Generally, any or all of the first and second top metals 430, 440, the bottom metal 420, and the upper and lower terminals 460, 470 may be formed from suitable conductive materials such as Cu.

In FIG. 4A, the bottom metal 420 is illustrated as being located under the MIM capacitor 410. As seen, the MIM capacitor 410 and the bottom metal 420 may be separated by an electrically insulating separation layer 490, i.e., the MIM capacitor 410 and the bottom metal 420 are not electrically coupled to each other. The bottom metal 420 can be located under and very close to the MIM capacitor 410 because the bottom metal 420 is provided with an anchoring cap 425 on an upper surface of the bottom metal 420 (the side of the bottom metal 420 facing the MIM capacitor 410). Preferably, a thickness of the separation layer 490 is less than a thickness of the bottom metal 420. The separation layer 490 thickness may substantially range between 10 and 200 nm. Also, the bottom metal 420 thickness may substantially range between 100 and 3000 nm.

Recall that with reference to FIG. 3, the anchoring cap 425 can significantly reduce or even eliminate pumping that would otherwise occur due to thermal cycling. This means that the surface of the bottom metal 420 is not disturbed, which in turn means that even when the bottom metal 420 is located very close below the MIM capacitor 410, the dielectric layer 416 is prevented from being broken. As a result, the real estate of the semiconductor device 400 below the MIM capacitor 410 is available for signal routing purposes, which can be accomplished through the bottom metal 420. In other words, the bottom metal 420 may form at least a part of a signal routing path. This is a significant advantage relative to the conventional semiconductor devices (compare with FIG. 1) where conventional design rules prevent MIM capacitors from landing on top of a terminal, which effectively prevents signal routing below the MIM capacitors.

The semiconductor device 400 of FIG. 4B is slightly different from that of FIG. 4A in that there is no separation layer 490. Thus, one difference is that in FIG. 4B, the bottom metal 420 on the right is illustrated as being electrically coupled to the lower plate 414 of the MIM capacitor 410. For example, the lower plate 414 of the MIM capacitor 410 may make direct contact with the anchoring cap 425 of the bottom metal 420. When the lower plate 414 and the bottom metal 420 are electrically coupled, this has the desirable effect of reducing the equivalent series resistance (ESR) of the MIM capacitor 410.

As seen, the contact area between the MIM capacitor 410 and the bottom metal 420 is preferably maximized, i.e., it is desirable to have as much area of the lower plate 414 of the MIM capacitor 410 be in contact with the bottom metal 420. Maximizing the contact area helps to reduce the ESR even further. In some cases, the lower plate 414 can be merged into the bottom metal 420. For example, the bottom metal 420 itself can serve as the lower plate of the MIM capacitor 410 (not shown in FIGS. 4A-4B, detailed further below).

The semiconductor devices 400 of both FIGS. 4A and 4B may be encapsulated. As seen, first and second encapsulation layers 480, 485 may encapsulate any or all of the MIM capacitor 410 (including the upper and lower plates 412, 414 and the dielectric layer 416), the bottom metal 420, the anchoring caps 425, the first and second top metals 430, 440, the first and second capacitor interconnects 435, 445, and the multi-layer connector 450 (including the upper and lower terminals 460, 470 and the terminal interconnect 465). The first and second encapsulation layers 480, 485 may be formed of materials such as SiO₂, SiN, SiON, and organic polymers. Also, the first and second encapsulation layers 480, 485 may be formed from same or different materials.

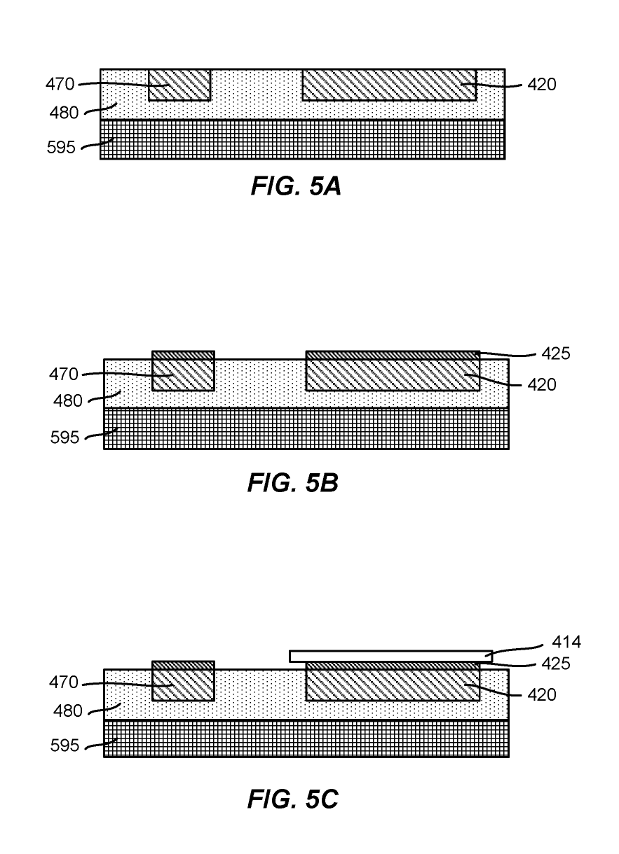

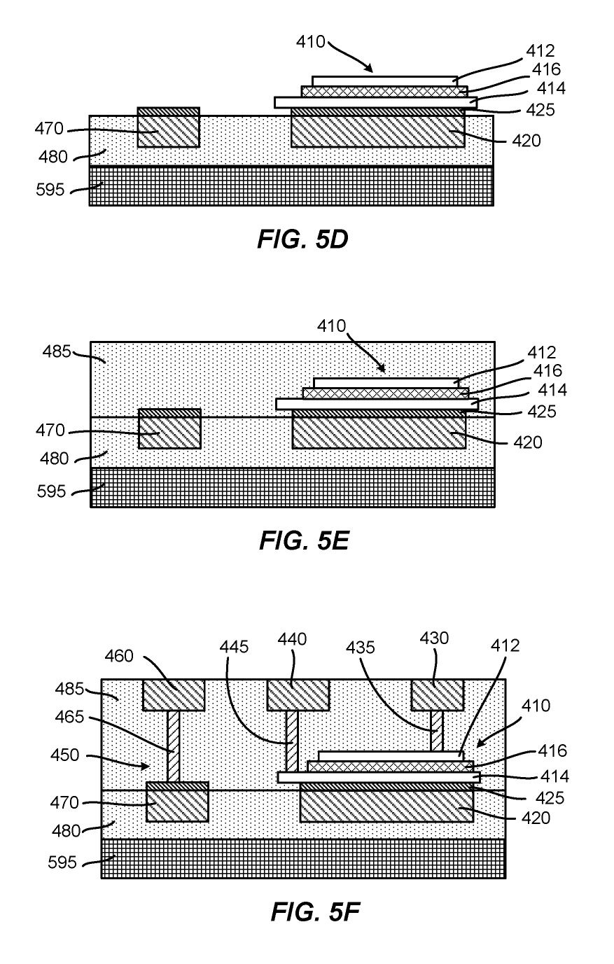

FIGS. 5A-5F illustrate various fabrication stages of an example process to manufacture a semiconductor device. The illustrated stages may be related to the manufacture of the semiconductor device 400 illustrated in FIG. 4B. FIG. 5A illustrates a stage in which one or more lower conductors such as the bottom metal 420 and/or the lower terminal 470. As seen, a substrate 595 may be formed. The substrate 595 may be a silicon (Si), glass or laminate substrate. On or above the substrate 595, a first encapsulation layer 480 may be formed. The first encapsulation layer 480 may be a SiO₂ layer or an organic polymer layer. The bottom metal 420 and/or the lower terminal 470 may be formed in the first encapsulation layer 480. The bottom metal 420 and/or the lower terminal 470 may be formed of Cu.

In one aspect, the bottom metal 420 and/or the lower terminal 470 may be formed through a damascene process. This is a process that involves patterning the first encapsulation layer 480 to form trenches, applying a barrier layer (e.g., Ta or TiN) over the patterned first encapsulation layer 480, applying a seed layer (e.g., a Cu seed layer) over the barrier layer, filling the pattern (e.g., by electrochemical deposition (ECD)), and then polishing (e.g., CMP) to remove excess Cu and to planarize the filled and patterned surface.

FIG. 5B illustrates a stage in which the anchoring caps 425 may be formed on the lower conductors, i.e., on the bottom metal 420 and/or the lower terminal 470. While not specifically shown in FIG. 5B, the anchoring caps 425 may be formed from anchoring materials such as the anchoring materials 322 illustrated in FIG. 3 including any one or more of Co, Mn, CoWP, CoSnP and Pd, or any other conductive material that has pumping resistance qualities. In one aspect, the anchoring caps 425 may be formed through a selective growth of the anchoring material 322.

FIG. 5C illustrates a stage in which the lower plate 414 of the MIM capacitor 410 may be formed. As seen, the lower plate 414 of the MIM capacitor 410 may be formed to be electrically coupled to the bottom metal 420. For example, the lower plate 414 may directly contact the anchoring cap 425 of the bottom metal 420. In an aspect, the lower plate 414 may be formed through a patterning process in which a conductive metal is deposited and patterned to form the lower plate 414. Examples of such conductive metals may include Ti, TiN, Ta, and TaN among others.

FIG. 5D illustrates a stage in which the MIM capacitor 410 formation may be completed. As illustrated, a high-K (high dielectric constant) dielectric layer 416 may be formed on the lower plate 414 and an upper plate 412 may be formed on the high-K dielectric layer 416. The high-K dielectric layer 416 may be formed from any one or more of SiN, AlO, ZrO, TiO, HfO and HfSiO, and the thickness range may substantially be 2-50 nm. The upper plate 412 may be formed from materials that are same or similar to the lower plate 414. One or both of the high-K dielectric layer 416 and the upper plate 412 may be formed through respective patterning processes.

FIG. 5E illustrates a stage in which a second encapsulation layer 485 may be formed over the MIM capacitor 410 and over the lower terminal 470. This second encapsulation layer 485 may be formed of the same or different material as the first encapsulation layer 480.

FIG. 5F illustrates a stage in which the upper conductors (e.g., any one or more of the first top metal 430, the second top metal 440, and the upper terminal 460) and/or the interconnections (e.g., any one or more of the first capacitor interconnect 435, the second capacitor interconnect 445, and the terminal interconnect 465) are formed. The upper conductors and/or the interconnections may be formed of Cu, and may be formed using a dual damascene (DD) process. While not illustrated, the anchoring material 322 can also be added to the upper conductors, i.e., can be added to any one or more of the first top metal 430, the second top metal 440, and the upper terminal 460 so as to restrict the Cu grain movements. For one skilled in the art, it is a relatively straight forward process from FIG. 5F to arrive at the semiconductor device 400 illustrated in FIG. 4B. Therefore, details will be omitted.

While not illustrated, an example process to manufacture the semiconductor device 400 illustrated in FIG. 4A can be very similar. The semiconductor device 400 of FIG. 4A may be arrived at by including a stage after the stage of FIG. 5B in which the separation layer 490 is formed over the anchoring caps 425 of the lower conductors (e.g., the bottom metal 420 and/or the lower terminal 470). Then the processing may proceed as illustrated in FIGS. 5C-5F to form the MIM capacitor 410, the upper conductors (e.g., any one or more of the first top metal 430, the second top metal 440, and the upper terminal 460) and the interconnections (e.g., any one or more of the first capacitor interconnect 435, the second capacitor interconnect 445, and the terminal interconnect 465).

The separation layer 490 can be formed from same or different materials as the first and/or the second encapsulation layers 480, 485. One (of which there could be several) purpose of the separation layer 490 is to allow for routing of signals through the bottom metal 420 below the MIM capacitor 410 while having them electrically decoupled.

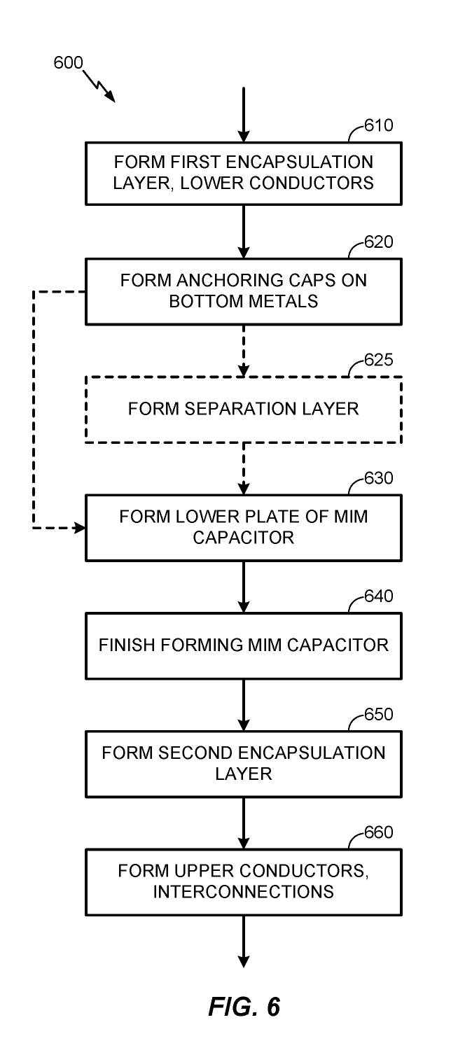

FIG. 6 illustrates a flow chart of an example method 600 to manufacture a semiconductor device such as the semiconductor devices 400 of FIGS. 4A and 4B. In block 610, the method 600 may include forming the first encapsulation layer 480 and one or more lower conductors (the bottom metal 420 and/or the lower terminal 470) in the first encapsulation layer 480. The first encapsulation layer 480, the bottom metal 420 and/or the lower terminal 470 may be formed on a substrate 595 (see FIG. 5A).

In block 620, the method 600 may include forming the anchoring caps 425 on the bottom metal 420 and/or the lower terminal 470 (see FIG. 5B). From block 620, in one aspect, the method 600 may proceed directly to block 630 (see FIG. 5C) of forming the lower plate 414 of the MIM capacitor 410. In this aspect, the MIM capacitor 410 can be electrically coupled to the bottom metal 420 so as to reduce the ESR of the MIM capacitor 410.

In an alternative aspect, the method 600 may proceed from block 620 to block 625 of forming the separation layer 490 over the bottom metal 420 and/or the lower terminal 470, and then to block 630. In this alternative aspect, forming a signal routing path under the MIM capacitor 410 is permitted. Then the method 600 may include finishing the formation of the MIM capacitor 410 in block 640 (see FIG. 5D), forming the second encapsulation layer 485 in block 650 (see FIG. 5E), and forming the upper conductors (e.g., any one or more of the first top metal 430, the second top metal 440, and the upper terminal 460) and the interconnections (e.g., any one or more of the first capacitor interconnect 435, the second capacitor interconnect 445, and the terminal interconnect 465) in block 660 (see FIG. 5E).

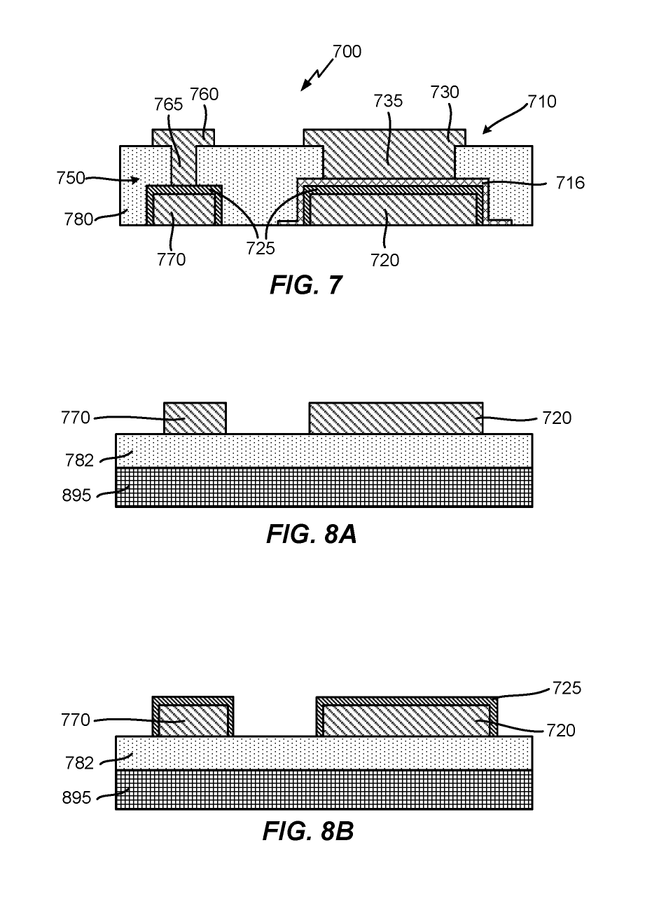

FIG. 7 illustrates an embodiment of a semiconductor device 700 according to another aspect of the present disclosure. The semiconductor device 700 may comprise a MIM capacitor 710 and/or a multi-layer connector 750. An encapsulation layer 780 may encapsulate, at least partially, the MIM capacitor 710 and/or the multi-layer connector 750. The MIM capacitor 710 may comprise a bottom metal 720, an anchoring cap 725 (which is electrically conductive) formed on the bottom metal 720, a dielectric layer 716 (preferably high-K dielectric), and a capacitor interconnect 735 on the dielectric layer 716. A top metal 730 may be electrically coupled to the capacitor interconnect 735. For example, the top metal 730 may be formed on the capacitor interconnect 735. In an aspect, the top metal 730 and the capacitor interconnect 735 may be a single element. Then the top and bottom metals 730, 720 may actually form the upper and lower plates of the MIM capacitor 710.

The multi-layer connector 750 may comprise an upper terminal 760, a lower terminal 770 and a terminal interconnect 765. The terminal interconnect 765 may be electrically coupled to both the upper and lower terminals 760, 770. In this way, the multi-layer connector 750 may enable electrical connections between devices above and below the multi-layer connector 750 (not shown). Also while not shown, electrical connections to and from devices in a same layer can be made. The upper terminal 760 may be formed on the terminal interconnect 765. Alternatively, the upper terminal 760 and the terminal interconnect 765 may be a single element. Generally, any or all of the top metal 730, the bottom metal 720, and the upper and lower terminals 760, 770 may be formed from suitable conductive materials such as Cu.

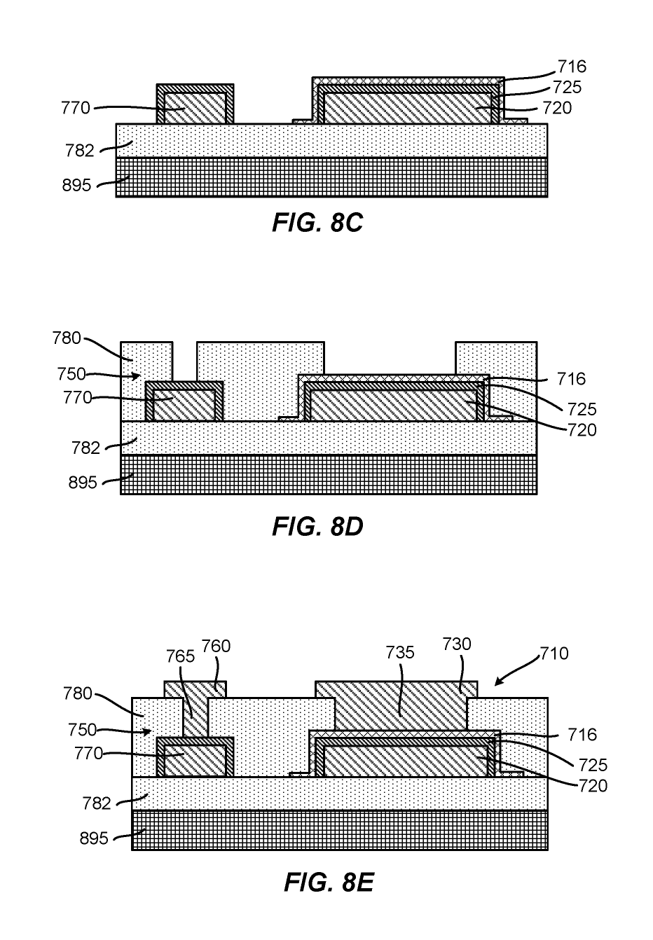

FIGS. 8A-8E illustrate various fabrication stages of another example process to manufacture a semiconductor device. In this instance, the stages may be related to a semi-additive process (SAP) of manufacturing a semiconductor device such as the semiconductor device 700. FIG. 8A illustrates a stage in which an insulating layer 782 may be formed on or above a substrate 895. The substrate 895 may be a silicon (Si) substrate, a glass or a laminate substrate and the insulating layer 782 may be a SiO₂ layer or an organic polymer layer. One or more lower conductors may be formed on or above the insulating layer 782. In FIG. 8A, the bottom metal 720 and the lower terminal 770, one or both of which may be formed of Cu, are examples of the lower conductors.

FIG. 8B illustrates a stage in which the anchoring caps 725 may be formed on the lower conductors—the bottom metal 720 and/or the lower terminal 770. While not shown in FIG. 8B, the anchoring caps 725 may be formed from anchoring materials such as the anchoring materials 322 of FIG. 3 including any one or more of Co, Mn, CoWP, CoSnP and Pd, or any other conductive material that has pumping resistance qualities. In one aspect, the anchoring caps 725 may be formed through a selective growth of the anchoring material 322. Note that the anchoring caps 725 can be on the top surface of the bottom metal 720 and/or the lower terminal 770. As illustrated, the anchoring caps 725 may also be on one or both of the side surfaces of the bottom metal 720 and/or the lower terminal 770.

FIG. 8C illustrates a stage in which a high-K dielectric layer 716 may be formed on the bottom metal 720. In particular, the high-K dielectric layer 716 can be formed on the anchoring cap 725 of the bottom metal 720. The high-K dielectric layer 716 may also be formed on a side surface of the bottom metal 720, and may extend from the side surface of the bottom metal 720 as well. Recall that in the discussion above with reference to FIG. 7, the bottom metal 720 may serve as the lower plate of the MIM capacitor 710. The high-K dielectric layer 716 may be formed by depositing a high-K dielectric material and then patterned as necessary.

FIG. 8D illustrates a stage in which the encapsulation layer 780 may be formed over the high-K dielectric layer 716 and/or over the lower terminal 770. The encapsulation layer 780 may have openings that expose at least some portions of the lower terminal 770 and the high-K dielectric layer 716. For example, the encapsulation layer 780, which may be of the same or different material as the insulating layer 782 (e.g., organic polymer, SiO₂, SiN, SiON) may be initially formed to cover the lower terminal 770 and the high-K dielectric layer 716. The openings to expose the lower terminal 770 and the high-K dielectric layer 716 may be formed, e.g., through patterning of the encapsulation layer 780. While not shown, in some cases, the opening may be larger than the bottom metal 720. For example, the entire top and side of the bottom metal 720 may be exposed.

FIG. 8E illustrates a stage in which the upper conductors (e.g., the top metal 730 and/or the upper terminal 760) and the interconnections (e.g., the capacitor interconnect 735 and/or the terminal interconnect 765) may be formed. For example, conductive material such as Cu may be deposited to fill the exposed openings to the high-K dielectric layer 716 and the lower terminal 770 to thereby form the capacitor interconnect 735 and the terminal interconnect 765, and the top metal 730 and the upper terminal 760 may then be formed. Note that the top metal 730 and the capacitor interconnect 735 may be formed in a continuous process, i.e., the two may be formed as a single element. Similarly, the upper terminal 760 and the terminal interconnect 765 may be formed in a continuous process. In an aspect, anchoring materials 322 can be added to the top metal 730 and the upper terminal 760 to restrict Cu grain movement (not shown).

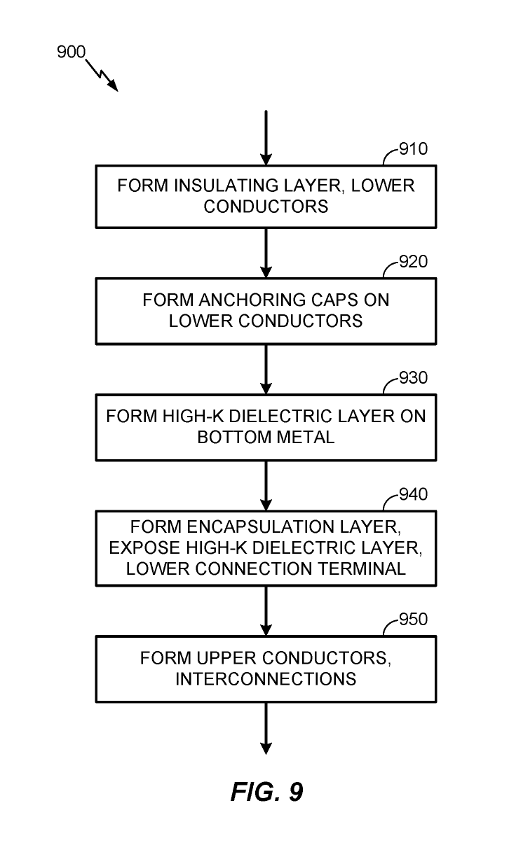

FIG. 9 illustrates a flow chart of an example method 900 to manufacture a semiconductor device such as the semiconductor device 700. In block 910, the method 900 may include forming the insulating layer 782 and one or more lower conductors (the bottom metal 720 and/or the lower terminal 770) on the insulating layer 782. The insulating layer 782 and the bottom metal 720 and/or the lower terminal 770 may be formed on a substrate 895 (see FIG. 8A).

In block 920, the method 900 may include forming the anchoring caps 725 on the bottom metal 720 and/or the lower terminal 770 (see FIG. 8B). In block 930, the method 900 may include forming the high-K dielectric layer 716 on the bottom metal 720 (see FIG. 8C). Then the method 900 may include forming the encapsulation layer 780 with openings in block 940 (see FIG. 8D), and forming the upper conductors (the top metal 730 and/or the upper terminal 760) and the interconnections (capacitor interconnect 735 and/or the terminal interconnect 765) in block 950 (see FIG. 8E).

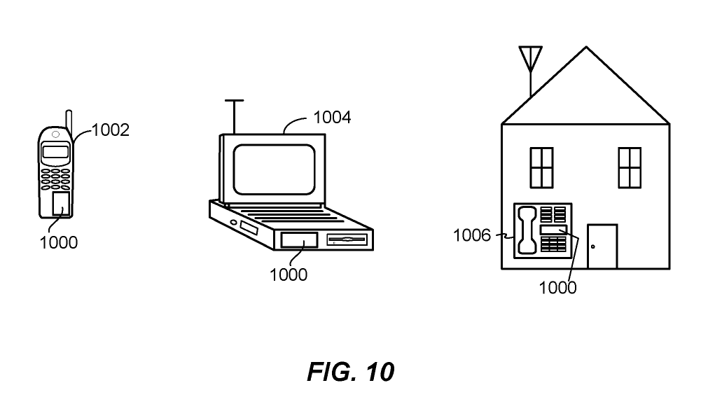

FIG. 10 illustrates various electronic devices that may be integrated with any of the aforementioned semiconductor devices 400, 700. For example, a mobile phone 1002, a laptop computer 1004, and a fixed location terminal 1006 may include an integrated device 1000 as described herein. The integrated device 1000 may have incorporated therein any of the semiconductor devices 400, 700 described herein. The mobile phone 1002, the laptop computer 1004, and the fixed location terminal 1006 illustrated in FIG. 10 are merely exemplary. Other electronic devices may also feature the integrated device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer-readable media embodying a method for manufacturing a semiconductor device. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps, and/or actions of the method claims in accordance with the embodiments of the invention described herein need not be performed in any particular order. Furthermore, although elements of the invention may be described or claimed in the singular, the plural is contemplated unless limitation to the singular is explicitly stated.

1. A semiconductor device, comprising:
a bottom metal with an anchoring cap formed thereon;
a metal-insulator-metal (MIM) capacitor formed above the bottom metal;
a first top metal electrically coupled to an upper plate of the MIM capacitor through a first capacitor interconnect; and
a second top metal electrically coupled to a lower plate of the MIM capacitor through a second capacitor interconnect,
wherein at least a portion of the bottom metal overlaps at least a portion of the lower plate of the MIM capacitor.

2. The semiconductor device of claim 1, further comprising:
a separation layer formed between the bottom metal and the lower plate of the MIM capacitor so as to electrically separate the bottom metal and the MIM capacitor.

3. The semiconductor device of claim 2, wherein a thickness of the separation layer is less than a thickness of the bottom metal.

4. The semiconductor device of claim 2, further comprising:
a signal routing path formed below the MIM capacitor,
wherein the bottom metal forms at least a part of the signal routing path.

5. The semiconductor device of claim 1, wherein the bottom metal is electrically coupled to the lower plate of the MIM capacitor.

6. The semiconductor device of claim 1, wherein the bottom metal is formed of copper (Cu).

7. The semiconductor device of claim 1, wherein the anchoring cap is formed on an upper surface of the bottom metal facing the lower plate of the MIM capacitor.

8. The semiconductor device of claim 1, wherein the anchoring cap is formed of any one or more of Co, Mn, CoWP, CoSnP, and Pd.

9. The semiconductor device of claim 1,
wherein the MIM capacitor includes the lower plate formed above the bottom metal, the upper plate formed above the lower plate, and a dielectric layer sandwiched in between the lower plate and the upper plate, and
wherein the upper plate, the dielectric layer, and the lower plate of the MIM capacitor are all substantially flat.

10. The semiconductor device of claim 9, wherein the dielectric layer of the MIM capacitor is a high-K dielectric layer.

11. The semiconductor device of claim 1, wherein the first top metal and the second top metal are formed above the upper plate of the MIM capacitor.

12. The semiconductor device of claim 1, wherein the semiconductor device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

13. A method of manufacturing a semiconductor device, the method comprising:
forming a bottom metal with an anchoring cap thereon;
forming a metal-insulator-metal (MIM) capacitor above the bottom metal;
forming a first top metal electrically coupled to an upper plate of the MIM capacitor through a first capacitor interconnect; and
forming a second top metal electrically coupled to a lower plate of the MIM capacitor through a second capacitor interconnect,
wherein the semiconductor device is formed such that at least a portion of the bottom metal overlaps at least a portion of the lower plate of the MIM capacitor.

14. The method of claim 13, further comprising:
forming a separation layer between the bottom metal and the lower plate of the MIM capacitor so as to electrically separate the bottom metal and the MIM capacitor.

15. The method of claim 14, wherein the separation layer is formed such that a thickness of the separation layer is less than a thickness of the bottom metal.

16. The method of claim 14, further comprising:
forming a signal routing path below the MIM capacitor,
wherein the bottom metal is formed such that the bottom metal is at least a part of the signal routing path.

17. The method of claim 13, wherein the bottom metal is formed to be electrically coupled to the lower plate of the MIM capacitor.

18. The method of claim 13, wherein the anchoring cap is formed on an upper surface of the bottom metal facing the lower plate of the MIM capacitor.

19. The method of claim 13,
wherein forming the MIM capacitor comprises:
forming the lower plate above the bottom metal;
forming the upper plate above the lower plate; and
forming a dielectric layer so as to be sandwiched in between the lower plate and the upper plate, and
wherein the upper plate, the dielectric layer, and the lower plate of the MIM capacitor are all formed to be substantially flat.

20. The method of claim 19, wherein the dielectric layer of the MIM capacitor is formed with a high-K dielectric layer.

21. The method of claim 13, wherein the first top metal and the second top metal are formed above the upper plate of the MIM capacitor.

22. A semiconductor device, comprising:
a metal-insulator-metal (MIM) capacitor; and
a top metal formed on the MIM capacitor,
wherein the MIM capacitor comprises:
a bottom metal with an anchoring cap formed thereon,
a dielectric layer formed on the bottom metal, and
a capacitor interconnect formed on the dielectric layer, and
wherein the top metal is formed on and is electrically coupled to the capacitor interconnect.

23. The semiconductor device of claim 22, wherein the anchoring cap is formed on an upper surface of the bottom metal facing the dielectric layer such that the dielectric layer is formed on at least a portion of the anchoring cap.

24. The semiconductor device of claim 23, wherein the anchoring cap is also formed on a side surface of the bottom metal.

25. The semiconductor device of claim 22, wherein the dielectric layer extends from a side surface of the bottom metal.

26. A method of manufacturing a semiconductor device, the method comprising:
forming a metal-insulator-metal (MIM) capacitor; and
forming a top metal on the MIM capacitor,
wherein forming the MIM capacitor comprises:
forming a bottom metal and an anchoring cap on the bottom metal;
forming a dielectric layer on the bottom metal; and
forming a capacitor interconnect on the dielectric layer, and
wherein the top metal is formed on and electrically coupled to the capacitor interconnect.

27. The method of claim 26, wherein the anchoring cap is formed on an upper surface of the bottom metal facing the dielectric layer such that the dielectric layer is formed on at least a portion of the anchoring cap.

28. The method of claim 27, wherein the anchoring cap is also formed on a side surface of the bottom metal.

29. The method of claim 26, wherein the dielectric layer is formed to extend from a side surface of the bottom metal.
